(19) United States
(12) Patent Application Publication
(10) Pub. No.: US 2023/0223456 A1
(43) Pub. Date: Jul. 13, 2023

(54) VERTICAL SEMICONDUCTOR DEVICE HAVING CONDUCTIVE LAYER, METHOD OF MANUFACTURING VERTICAL SEMICONDUCTOR DEVICE, AND ELECTRONIC DEVICE

(71) Applicant: INSTITUTE OF MICROELECTRONICS, CHINESE ACADEMY OF SCIENCES, Beijing (CN)

(72) Inventor: Huilong ZHU, Poughkeepsie, NY (US)

(21) Appl. No.: 18/009,410

(22) PCT Filed: Mar. 23, 2021
(86) PCT No.: PCT/CN2021/082329

§ 371 Date: Dec. 9, 2022

(30) Foreign Application Priority Data
Jun. 12, 2020 (CN) 202010539695.6

(51) Int. Cl. H01L 29/423; H01L 29/786; H01L 29/06; H01L 29/66; H01L 29/775; H01L 27/088; H01L 21/8234

(52) U.S. Cl. CPC H01L 29/42392; H01L 29/78696; H01L 29/0673; H01L 29/66545; H01L 29/775; H01L 29/66469; H01L 27/088; H01L 21/823412; H01L 21/823418

(57) ABSTRACT

Disclosed are a vertical semiconductor device having a conductive layer, a method of manufacturing the vertical semiconductor device, and an electronic device including the vertical semiconductor device. According to an embodiment, the semiconductor device may include: a substrate; a first metallic layer, a channel layer and a second metallic layer which are sequentially disposed on the substrate; and a gate stack formed around at least a part of a periphery of the channel layer, wherein each of the first metallic layer, the second metallic layer, and the channel layer is of single crystal structure.

### CROSS REFERENCE TO RELATED APPLICATION(S)

This application is a Section 371 National Stage Application of International Application No. PCT/CN2021/082329, filed on Mar. 23, 2021, which claims priority to Chinese Patent Application No. 202010539695.6, filed on Jun. 12, 2020 and entitled “Vertical semiconductor device having conductive layer, method of manufacturing vertical semiconductor device, and electronic device”, the entire content of which is incorporated herein in its entirety by reference.

### TECHNICAL FIELD

The present disclosure relates to the field of semiconductors, and more particularly, to a vertical semiconductor device having a conductive layer especially a metallic layer, a method of manufacturing the vertical semiconductor device, and an electronic device including the vertical semiconductor device.

### BACKGROUND

In a planar device such as a Metal Oxide Semiconductor Field Effect Transistor (MOSFET), a source, a gate and a drain are arranged in a direction substantially parallel to a substrate surface. Due to such an arrangement, it is difficult to further scale down the area occupied by the planar device or further reduce the manufacturing cost for the planar device. In contrast, in a vertical device, a source, a gate and a drain are arranged in a direction substantially perpendicular to a substrate surface. Therefore, it is easier to scale down the vertical device or reduce the manufacturing cost for the vertical device as compared to the planar device.

In the vertical device, a channel of single crystal material is desired, because using the single crystal material may reduce a channel resistance as compared with a polycrystalline material, and thus a plurality of vertical devices may be stacked, so as to achieve a high integration density. However, for the channel of single crystal material, on one hand, it is difficult to control a gate length, and on the other hand, it is difficult to provide a low resistance in a source/drain region.

### SUMMARY

In view of the above, the present disclosure aims to provide, among others, a vertical semiconductor device having a conductive layer especially a metallic layer to provide a low resistance in a source/drain region, a method of manufacturing the vertical semiconductor device, and an electronic device including the vertical semiconductor device.

According to an aspect of the present disclosure, there is provided a semiconductor device, including: a substrate; a first metallic layer, a channel layer and a second metallic layer which are sequentially disposed on the substrate; and a gate stack formed around at least a part of a periphery of the channel layer, wherein each of the first metallic layer, the second metallic layer, and the channel layer is of single crystal structure.

According to another aspect of the present disclosure, there is provided a semiconductor device, including: a substrate; a first conductive layer, a first source/drain layer, a channel layer, a second source/drain layer, and a second conductive layer which are sequentially disposed on the substrate; and a gate stack formed around at least a part of a periphery of the channel layer, wherein each of the first conductive layer, the second conductive layer, the first source/drain layer, the second source/drain layer, and the channel layer is of single crystal structure. The conductive layer may include a doped semiconductor material.

According to another aspect of the present disclosure, there is provided a method of manufacturing a semiconductor device, including: sequentially forming a first metallic layer, a channel layer and a second metallic layer on a substrate; patterning the first metallic layer, the channel layer and the second metallic layer into a predetermined shape; and forming a gate stack around at least a part of a periphery of the channel layer.

According to another aspect of the present disclosure, there is provided a method of manufacturing a semiconductor device, including: sequentially forming a first conductive layer, a first source/drain layer, a channel layer, a second source/drain layer, and a second conductive layer on a substrate; patterning the first conductive layer, the first source/drain layer, the channel layer, the second source/drain layer, and the second conductive layer into a predetermined shape; and forming a gate stack around at least a part of a periphery of the channel layer.

According to another aspect of the present disclosure, there is provided an electronic device including an integrated circuit formed by the above-mentioned semiconductor device.

According to an embodiment of the present disclosure, a gate stack is formed around at least a part of a periphery of a channel layer and a channel may be formed in the channel layer, so that a gate length is substantially determined by a thickness of the channel layer. The channel layer may be formed by e.g. epitaxial growth, so that the thickness of the channel layer may be well controlled. Therefore, the gate length may be well controlled. In addition, conductive layers, especially metallic layers, are arranged on two sides of the channel layer, which may be source/drain regions or parts of the source/drain regions, thereby reducing a source/drain resistance.

### BRIEF DESCRIPTION OF THE DRAWINGS

The above and other objects, features, and advantages of the present disclosure will become more apparent from following descriptions on embodiments thereof with reference to attached drawings, in which:

FIGS. 1(a) to 8(c) are schematic views showing a process of manufacturing a semiconductor device according to an embodiment of the present disclosure; and

FIGS. 9 to 12 are schematic views showing a process of manufacturing a semiconductor device according to another embodiment of the present disclosure.

Throughout the drawings, the same or similar reference numbers denote the same or similar elements.

### DETAILED DESCRIPTION OF EMBODIMENTS

Hereinafter, descriptions are given with reference to embodiments shown in the attached drawings. However, it is to be understood that these descriptions are illustrative and not intended to limit the present disclosure. Further, in the following, known structures and technologies are not described to avoid obscuring the present disclosure unnecessarily.

In the drawings, various structures according to the embodiments are schematically shown. However, they are not drawn to scale, and some features may be enlarged while some features may be omitted for sake of clarity. Moreover, shapes and relative sizes and positions of regions and layers shown in the drawings are also illustrative, and deviations may occur due to manufacture tolerances and technique limitations in practice. Those skilled in the art may also devise regions/layers of other different shapes, sizes, and relative positions as desired in practice.

In the context of the present disclosure, when a layer/element is recited as being “on” a further layer/element, the layer/element may be disposed directly on the further layer/element, or otherwise there may be an intervening layer/element interposed therebetween. Further, if a layer/element is “on” a further layer/element in an orientation, then the layer/element may be “under” the further layer/element when the orientation is turned.

A vertical semiconductor device according to an embodiment of the present disclosure may include a first conductive layer, a channel layer, and a second conductive layer that are sequentially disposed on a substrate. Respective layers may be adjacent to each other. Of course, there may be other semiconductor layer(s), e.g. a leakage suppression layer and an ON-state current enhancement layer (i.e., a semiconductor layer having a band gap greater than or less than that of adjacent layers) between adjacent layers. Source/drain regions of the device (which may be referred to as “a first source/drain region” and “a second source/drain region”, respectively) may be formed in the first conductive layer and the second conductive layer themselfs. Alternatively, a first source/drain layer may be between the first conductive layer and the channel layer, and a second source/drain layer may be between the second conductive layer and the channel layer. The first source/drain region and the second source/drain region may also be formed in the first source/drain layer and the second source/drain layer. In addition, a channel region of the device may be formed in the channel layer.

Each of the first conductive layer and the second conductive layer may be a material layer with high conductivity, such as a metallic layer or a doped semiconductor layer. In the presence of the first source/drain layer and the second source/drain layer, an ohmic contact may be formed between the first conductive layer and the first source/drain layer, and an ohmic contact may be formed between the second conductive layer and the second source/drain layer, so as to reduce resistance. In the absence of the first source/drain layer and the second source/drain layer, a Schottky junction may be formed between the first conductive layer (especially the metallic layer) and the channel layer, and a Schottky junction may be formed between the second conductive layer (especially the metallic layer) and the channel layer, such that a Schottky device may be formed.

Each of the first conductive layer, the first source/drain layer, the channel layer, the second source/drain layer and the second conductive layer may be of single crystal material, so as to have a high carrier mobility and a low leakage current, and thereby improving a device performance. Such layers may be formed by growth, such as epitaxial growth. Due to the epitaxial growth, at least some adjacent layers may have a clear crystal interface therebetween, and for at least some of the interfaces, at least a part of the interface or even the entire interface may be a coherent interface.

A gate stack may be formed around at least a part of a periphery of the channel layer, and may control the on/off of the channel region. According to an embodiment, the gate stack, especially an end portion of the gate stack close to the channel layer, may be self-aligned with the channel layer. For example, a peripheral sidewall of the channel layer may be recessed relatively inward. In this way, an end portion of the formed gate stack may be embedded in the relative recess of the channel layer, reducing an overlap with the source/drain region, and helping to reduce a parasitic capacitance between a gate and a source/drain. Accordingly, a gate length may be determined by a thickness of the channel layer itself, instead of being determined depending on an etching timing as in a conventional technique. The channel layer may be formed by epitaxial growth, for example, so that the thickness of the channel layer may be well controlled. Therefore, the gate length may be well controlled.

Such semiconductor device may be manufactured, for example, as follows.

The first conductive layer, the channel layer and the second conductive layer may be sequentially formed on the substrate. Alternatively, the first source/drain layer may be formed between the first conductive layer and the channel layer, and the second source/drain layer may be formed between the channel layer and the second conductive layer. As described above, each layer may be formed on the substrate by epitaxial growth, and each layer is kept as a single crystal system. During growth, a thickness of each layer grown, especially the thickness of the channel layer, may be controlled.

For the sequentially disposed first conductive layer, channel layer and second conductive layer (and optionally, the first source/drain layer and the second source/drain layer), an active region may be defined in these layers. For example, these layers may be selectively etched in sequence such that each layer is etched into a desired shape. In general, the active region may be columnar (for example, cylindrical). In order to facilitate a connection of the source/drain region formed in the first conductive layer in the subsequent process, the etching of the first conductive layer may be applied to only an upper portion of the first conductive layer, so that a lower portion of the first conductive layer may extend beyond a periphery of the upper portion of the first conductive layer. Then, the gate stack may be formed around the periphery of the channel layer.

In addition, the periphery (and optionally, peripheries of the first source/drain layer and the second source/drain layer) of the channel layer may be recessed inward relative to peripheries of the first conductive layer and the second conductive layer, so as to define a space for accommodating the gate stack. For example, this may be achieved by selective etching. In this case, the gate stack may be embedded in the recess.

The present disclosure may be presented in various forms, and some examples of which will be described below. In the following description, the selection of various materials is involved. For the selection of materials, etching selectivity is also considered in addition to considering their functions (for example, semiconductor materials are used to form active regions and dielectric materials are used to form electrical isolation). In the following description, the required etching selectivity may or may not be indicated. It should be clear to those skilled in the art that when etching a certain material layer is mentioned below, if it is not mentioned that other layers are also etched or the drawing does not show that other layers are also etched, then this etching may be selective, and the material layer may have etching selectivity with respect to other layers exposed to the same etching recipe.

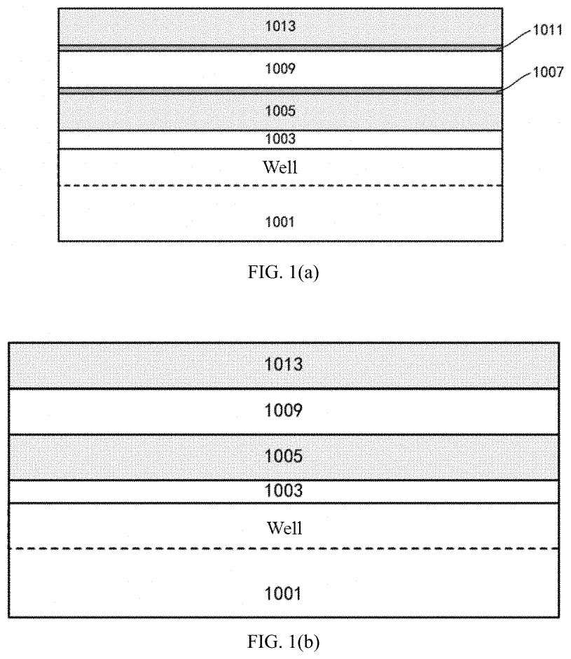

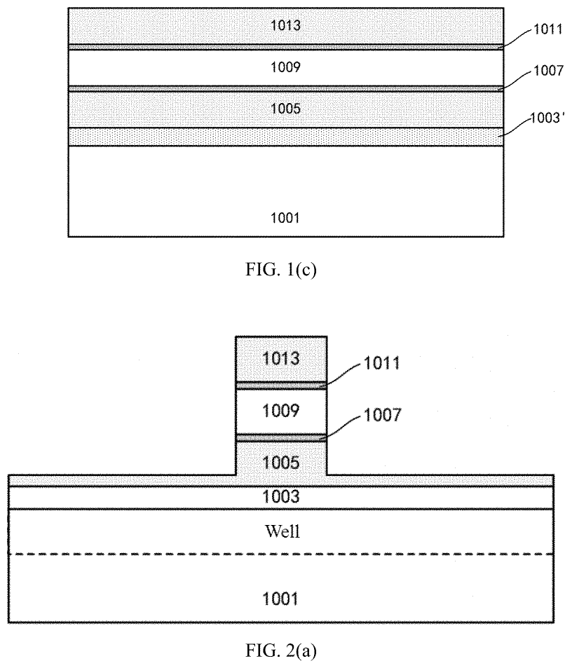

FIGS. 1(a) to 8(c) are schematic views showing a process of manufacturing a semiconductor device according to an embodiment of the present disclosure.

As shown in FIG. 1(a), a substrate 1001 is provided. The substrate 1001 may be a substrate in any form, for example, but not limited to, a bulk semiconductor material substrate such as a bulk silicon (Si) substrate, a Semiconductor On Insulator (SOI) substrate, a compound semiconductor substrate such as an SiGe substrate, or the like. Hereinafter, the bulk Si substrate will be described by way of example for the convenience of description.

In the substrate 1001, a well region may be formed by, for example, ion implantation or diffusion doping. For example, if a p-type device is to be formed, an n-type well region may be formed. If an n-type device is to be formed, a p-type well region may be formed. Well regions of different conductive types may be formed by impurities (a p-type impurity such as B or BF₂, an n-type impurity such as P or As, etc.) of corresponding conductive types. Annealing may be performed to activate an injected impurity. A doping concentration in the well region may be, for example, about 1E17 cm⁻³ to 1E19 cm⁻³.

Material layers (each of these material layers may be formed into a single crystal structure to ensure that a channel layer in the active region may have single crystal structure so as to reduce a channel resistance) for disposing the active region may be formed on the substrate 1001. In one example, in order to suppress a leakage, the leakage suppression layer may be formed before forming the material layer for the active region.

For example, the leakage suppression layer may include a semiconductor material such as Si, as shown in 1003 in FIG. 1 (a). The leakage suppression layer 1003 of the semiconductor material may be formed by, for example, epitaxial growth, and may be doped into a conductive type opposite to the well region by ion implantation or by in situ doping during epitaxial growth. Accordingly, a pn junction may be formed between the leak suppression layer 1003 and the well region. In general, compared with a Schottky junction leakage to be formed later, a pn junction leakage is relatively small.

Alternatively, the leakage suppression layer may include an insulating material, as shown in 1003′ in FIG. 1(c). The leakage suppression layer 1003′ of the insulating material may be formed by growth, such as chemical vapor deposition (CVD). In order to reduce a crystal defect, a difference between a lattice constant of the leakage suppression layer 1003′ and a lattice constant of the substrate 1001 may be within a range of about +/−2%. For example, the leakage suppression layer 1003′ may include SrTiO₃, (LaY)₂O₃, LaAlO₃ or LaLuO₃, but the present disclosure is not limited thereto.

On the leakage suppression layer 1003 or 1003′, a first conductive layer 1005, a first source/drain layer 1007, a channel layer 1009, a second source/drain layer 1011 and a second conductive layer 1013 may be formed sequentially.

The first conductive layer 1005 and the second conductive layer 1013 may have high conductivity. For example, the first conductive layer 1005 and the second conductive layer 1013 may include a metallic material such as NiSi₂ or CoSi₂, and may be formed by growth such as CVD. Alternatively, the first conductive layer 1005 and the second conductive layer 1013 may include a semiconductor material, may be formed by, for example, epitaxial growth, and may be doped (for example, doped in situ during growth) to have high conductivity, such as doped GaAs or doped GaAs:Si. The first conductive layer 1005 may include a material identical to a material of the second conductive layer 1013. Of course, it is also possible for the first conductive layer 1005 to include a material different from the material of the second conductive layer 1013. In order to reduce the crystal defect, a difference between a lattice constant of each of the first conductive layer 1005 and the second conductive layer 1013 and the lattice constant of the substrate 1001 is within the range of about +/−2%. The first conductive layer 1005 and the second conductive layer 1013 may form the source/drain region or a part of the source/drain region (for example, as a contact portion of the source/drain region to contact an interconnection). Thicknesses of the first conductive layer 1005 and the second conductive layer 1013 are about 5 nm to 50 nm, for example.

The first source/drain layer 1007, the channel layer 1009, and the second source/drain layer 1011 may be semiconductor material layers formed by, for example, epitaxial growth. The first source/drain layer 1007 and the second source/drain layer 1011 may be used to form (a part of) the source/drain region, so the first source/drain layer 1007 and the second source/drain layer 1011 may be doped (for example, doped in situ during growth) to a conductive type corresponding to a type of the device to be formed, e.g. doped to p-type for the p-type device, and doped to n-type for the n-type device. The doping concentration is about 1E19 cm⁻³ to 1E21 cm⁻³. Thicknesses of the first source/drain layer 1007 and the second source/drain layer 1011 may be about 2 nm to 5 nm, for example. Here, the first source/drain layer 1007 and the second source/drain layer 1011 are thinner than the first conductive layer 1005 and the second conductive layer 1013, so that a large part of the subsequently formed source/drain region has high conductivity to reduce the resistance. The first source/drain layer 1007 may include a material identical to a material of the second source/drain layer 1011, but the present disclosure is not limited thereto. In addition, the channel layer 1009 may be unintentionally doped, or lightly doped (for example, doped in situ during growth) to adjust a threshold voltage of the device. A thickness of the channel layer 1009 may be, for example, about 10 nm to 200 nm.

The first source/drain layer 1007, the channel layer 1009, and the second source/drain layer 1011 may include various suitable semiconductor materials, such as Si, SiGe, Ge, III-V compound semiconductors such as GaAs, etc. In order to reduce the crystal defect, a difference between a lattice constant of each of the first source/drain layer 1007, the channel layer 1009, and the second source/drain layer 1011 and the lattice constant of the substrate 1001 is within the range of about +/−2%. In one example, the first source/drain layer 1007, the channel layer 1009, and the second source/drain layer 1011 may include the same material such as Si. In other examples, adjacent ones of the first source/drain layer 1007, the channel layer 1009 and the second source/drain layer 1011 may have etching selectivity, for example, the first source/drain layer 1007 and the second source/drain layer 1011 may include Si, while the channel layer 1009 may include SiGe.

In examples shown in FIG. 1(a) and FIG. 1(c), highly doped semiconductor layers (1007, 1011) and conductive layers (1005, 1013) are respectively arranged on upper and lower sides of the channel layer 1009 to form the source/drain region. An ohmic contact may be formed between the highly doped semiconductor layers (1007, 1011) and the conductive layers (1005, 1013) to reduce the resistance. However, the present disclosure is not limited thereto. For example, as shown in FIG. 1(b), the highly doped semiconductor layer may be omitted, and the conductive layers 1005 and 1013 may be directly arranged on the upper and lower sides of the channel layer 1009. When each of the conductive layers 1005 and 1013 includes the metallic layer, a Schottky junction may be formed between the conductive layer 1005 and the channel layer 1009, and a Schottky junction may be formed between the conductive layer 1013 and the channel layer 1009, so that a Schottky device may be formed by the conductive layers 1005 and 1013 along with the channel layer 1009.

Each of such layers formed on the substrate 1001 is grown from a lower layer, so as to maintain the single crystal system. There may be a crystal interface and/or a doping concentration interface between the adjacent layers. In addition, at least a part of the interface between at least some adjacent layers may be the coherent interface.

Although FIGS. 1(a), 1(b) and 1(c) show different situations respectively, such situations may be combined in different ways. For example, the leakage suppression layer 1003 in FIG. 1(b) may be formed into the insulating material as shown in the leakage suppression layer 1003′ in FIG. 1(c), or the source/drain layers 1007 and 1011 may be omitted in FIG. 1(c). In the following description, the situation shown in FIG. 1(a) is mainly taken as an example for description. However, such description may also be applied to other situations such as those shown in FIGS. 1(b) and 1(c).

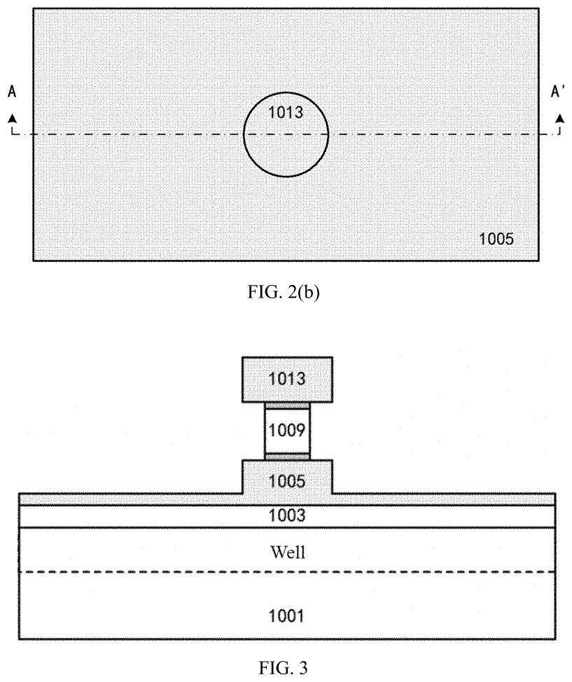

Next, the active region of the device may be defined. For example, this may be achieved as follows. Specifically, as shown in FIGS. 2(a) and 2(b) (FIG. 2(a) is a section view, and FIG. 2(b) is a top view, wherein a line AA′ shows an interception position of the section), a photoresist (not shown) may be formed, and the photoresist is patterned into a desired shape (substantially circular in this example) by photolithography (exposure and development). Selective etching, such as reactive ion etching (RIE), is performed sequentially on the second conductive layer 1013, the second source/drain layer 1011, the channel layer 1009, the first source/drain layer 1007 and the first conductive layer 1005, by using the patterned photoresist as a mask. Here, the etching may go into the first conductive layer 1005, without reaching a bottom surface of the first conductive layer 1005. In this way, the contact portion formed subsequently may easily fall onto the first conductive layer 1005. Accordingly, each of the second conductive layer 1013, the second source/drain layer 1011, the channel layer 1009, the first source/drain layer 1007, and an upper portion of the first conductive layer 1005 is formed into a column (in this example, a cylinder) after etching. The second conductive layer 1013, the second source/drain layer 1011, the channel layer 1009, the first source/drain layer 1007, and an upper portion of the first conductive layer 1005 define the active region. For example, RIE may be performed in a direction substantially perpendicular to the substrate surface, so that the column is also substantially perpendicular to the substrate surface. After that, the photoresist may be removed.

Here, a substantially circular (for example, about 10 nm to 100 nm in diameter) active region will lead to a formation of a nanowire device. However, the present disclosure is not limited thereto. For example, the active region may be patterned into a rectangle (for example, a length of the rectangle is about 10 nm to 10 μm to provide a sufficient device current, and a width of the rectangle is about 10 nm to 100 nm to achieve a good control of a short channel effect), so that a nanosheet device may be formed. Of course, the shape of the active region is not limited thereto.

In order to form a self-aligning gate stack, a peripheral sidewall of the channel layer 1009 may be relatively recessed (in this example, recessed in a transverse direction substantially parallel to the substrate surface). For example, as shown in FIG. 3, the channel layer 1009 may be selectively etched with respect to the first conductive layer 1005 and the second conductive layer 1013 by, for example, wet etching with TMAH solution. In order to accurately control an etching depth, the etching of the channel layer 1009 may be performed by atomic layer etching (ALE). Around a periphery of the channel layer 1009, the etching depth may be approximately the same. That is, the etched channel layer 1009 may keep substantially center aligned with the second conductive layer 1013, and a shape of the etched channel layer 1009 remains substantially the same (but reduced) as the the second conductive layer 1013. In this example, the first source/drain layer 1007 and the second source/drain layer 1011 also include Si, so the first source/drain layer 1007 and the second source/drain layer 1011 may also be etched. The shape of the etched first source/drain layer 1007 and the shape of the etched second source/drain layer 1011 may be substantially the same as that of the channel layer 1009, and the etched first source/drain layer 1007 and the etched second source/drain layer 1011 may be substantially center aligned with the channel layer 1009.

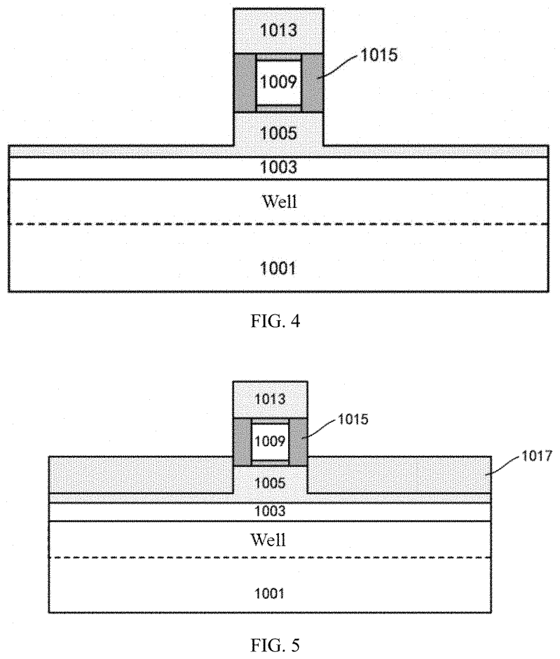

In a recess formed by the channel layer 1009 (and the first source/drain layer 1007 and the second source/drain layer 1011) relative to the first conductive layer 1005 and the second conductive layer 1013, the gate stack will be formed subsequently. In order to avoid an influence to the channel layer 1009 by subsequent processes or an affection to the formation of the subsequent gate stack due to an unnecessary material left in the recess, the recess may be filled with a material layer to occupy the space of the gate stack (therefore, the material layer may be called a “sacrificial gate”). For example, this may be achieved by depositing a nitride, followed by etching back, such as RIE, the deposited nitride. RIE may be performed in a vertical direction, so that the nitride may only remain in the recess to form a sacrificial gate 1015, as shown in FIG. 4. In this case, the above-mentioned recess may be fully filled with the sacrificial gate 1015.

An isolation layer may be formed around the active region to achieve electrical isolation. For example, as shown in FIG. 5, an oxide may be deposited on the structure shown in FIG. 4 and etched back to form an isolation layer 1017. Before etching back, a planarization treatment, such as chemical mechanical polishing (CMP) or sputtering, may be performed on the deposited oxide. Here, a top surface of the isolation layer 1017 may be between a top surface and a bottom surface of the channel layer 1009.

Next, a gate replacement process may be performed.

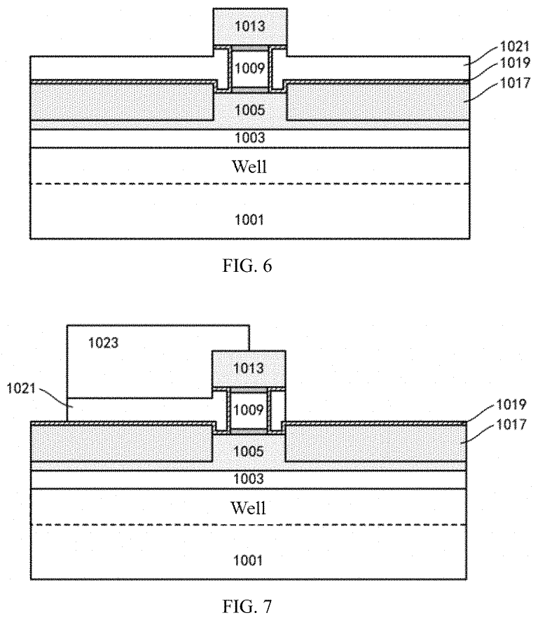

For example, as shown in FIG. 6, the sacrificial gate 1015 may be removed by selective etching to release the space in the recess. The gate stack may be formed in the released recess. Specifically, a gate dielectric layer 1019 and a gate conductor layer 1021 may be sequentially deposited, and the deposited gate conductor layer 1021 may be etched back so that a top surface of a part of the gate conductor layer 1021 outside the recess is not higher than and preferably lower than the top surface of the channel layer 1009. Before etching back, the planarization treatment such as CMP may be performed on the gate conductor layer. For example, the gate dielectric layer 1019 may include a high K gate dielectric such as HfO₂, and a thickness of the gate dielectric layer 1019 is about 1 nm to 5 nm. The gate conductive layer 1021 may include a work function adjusting metal and a gate conductive metal. Before forming the gate dielectric layer 1019, an oxide interface layer of about 0.5 nm to 2 nm, for example, may further be formed.

In this way, the end of the gate stack may be embedded into the recess, thus overlapping the entire height of the channel layer 1009. In addition, since a bottom surface of the gate stack defined by the top surface of the isolation layer 1017 is between the top surface and the bottom surface of the channel layer 1009, an overlap between the gate stack and the first conductive layer 1005 may be reduced. In addition, since a top surface of a part of the gate stack outside the recess is lower than the bottom surface of the channel layer 1009, an overlap between the gate stack and the second conductive layer 1013 may be reduced.

According to an embodiment, the gate conductor layer 1021 may contain a stress or a strain to improve the device performance. For example, for the p-type device, the gate conductor layer may have a tensile stress (such as TiN or W) to generate a compressive stress in the channel, while for the n-type device, the gate conductor layer may have the compressive stress to generate the tensile stress in the channel. Since an upper end of the active region is movable, such structure may generate much greater stress than a planar MOSFET or a FinFET, and therefore the performance may be improved by stress to a much higher degree.

Next, a shape of the gate stack may be adjusted to facilitate subsequent interconnection fabrication. For example, as shown in FIG. 7, a photoresist 1023 may be formed on the gate conductor layer 1021. The photoresist 1023 is, for example, patterned by photolithography to cover one part of the gate stack exposed outside the recess (in this example, a left half of the figure), and to expose the other part of the gate stack exposed outside the recess (in this example, a right half of the figure).

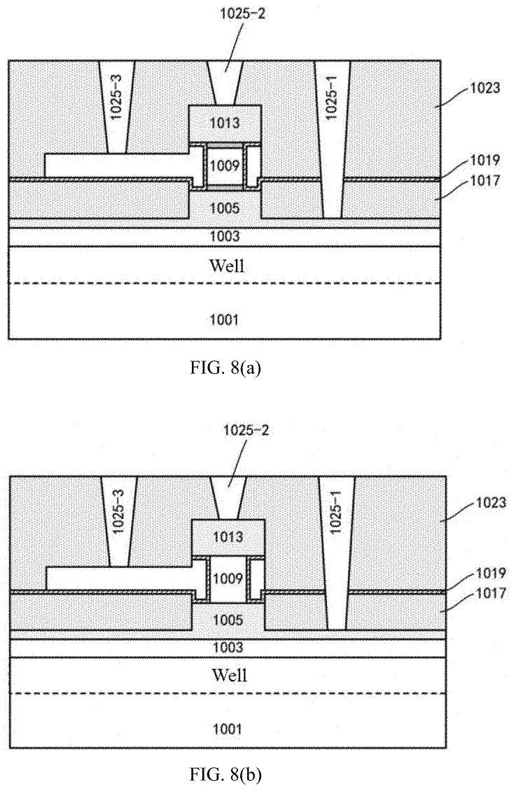

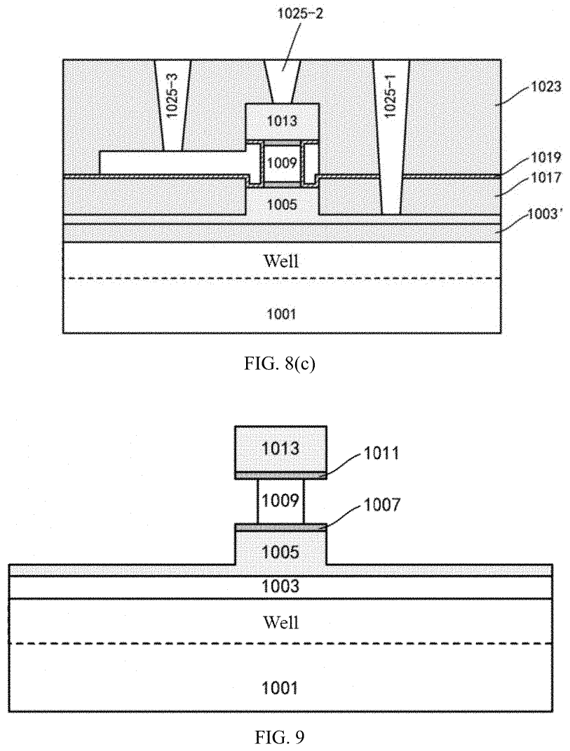

Next, as shown in FIG. 8(a), selective etching such as RIE may be performed on the gate conductor layer 1021 by using the photoresist 1023 as the mask. In this way, in addition to a part of the gate conductor layer 1021 left in the recess, a part of the gate conductor layer 1021 shielded by the photoresist 1019 may be retained. The part of the gate conductor layer 1021 shielded by the photoresist 1019 may be used as a landing pad to a contact portion (a contact portion 1025-3 described below) to the gate conductor layer 1021. According to another embodiment, selective etching such as RIE may also be performed on the gate dielectric layer 1019 (not shown in the figure). Afterwards, the photoresist 1023 may be removed.

Next, an interlayer dielectric layer 1023 may be formed. For example, an oxide may be deposited, and the planarization treatment such as CMP may be performed on the deposited oxide to form the interlayer dielectric layer 1023. In the interlayer dielectric layer 1023, a contact portion 1025-1 to the first conductive layer 1005, a contact portion 1025-2 to the second conductive layer 1013, and the contact portion 1025-3 to the gate conductor layer 1021 may be formed. Such contact portions may be formed by etching a hole in the interlayer dielectric layer 1023 and the isolation layer 1017 and filling the hole with a conductive material such as a metal (e.g., tungsten). A diffusion barrier layer, such as TiN, may be formed before depositing the metal.

Since the gate conductor layer 1021 extends beyond a periphery of the active region, the contact portion 1025-3 of the gate conductor layer 1021 may be easily formed. In addition, since the lower portion of the first conductive layer 1005 extends beyond the active region and there is no gate conductive layer 1021 above at least a part of the first conductive layer 1005, the contact portion 1025-1 of the first conductive layer 1005 may be easily formed.

As shown in FIG. 8(a), the semiconductor device according to this embodiment includes the first conductive layer 1005, the first source/drain layer 1007, the channel layer 1009, the second source/drain layer 1011 and the second conductive layer 1013 stacked in the vertical direction. A source/drain region is formed in the first conductive layer 1005 and the first source/drain layer 1007, and another source/drain region is formed in the second conductive layer 1013 and the second source/drain layer 1011. The channel layer 1009 is transversely recessed. The gate stack (1019/1021) is formed around the periphery of the channel layer 1009, and the end portion of the gate stack is embedded in the recess.

FIG. 8(b) shows a semiconductor device obtained by the operation described above (omitting the first source/drain layer 1007 and the second source/drain layer 1011) in combination with FIGS. 2(a) to 8(a) in the case shown in FIG. 1(b). The semiconductor device shown in FIG. 8(b) is substantially the same as that shown in FIG. 8(a), except that a Schottky device may be formed by the first conductive layer 1005 and the second conductive layer 1003 along with the channel layer 1009 when each of the first conductive layer 1005 and the second conductive layer 1003 is a metallic layer.

FIG. 8(c) shows a semiconductor device obtained by the operation (replacing the leakage suppression layer 1003 of semiconductor material by the leakage suppression layer 1003′ of insulating material) described above in combination with FIGS. 2(a) to 8(a) in the case shown in FIG. 1(c). The semiconductor device shown in FIG. 8(b) is substantially the same as that shown in FIG. 8(a), except that the leakage suppression layer is different from that shown in FIG. 8(a).

In the above embodiment, the first source/drain layer 1007 and the second source/drain layer 1011 include a material identical to a material of the channel layer 1009, and thus the first source/drain layer 1007 and the second source/drain layer 1011 are also relatively recessed in the process of causing the channel layer 1009 relatively recessed. However, the present disclosure is not limited thereto.

FIGS. 9 to 12 are schematic views showing a process of manufacturing a semiconductor device according to another embodiment of the present disclosure.

As shown in FIG. 9, according to the above description in combination with FIGS. 1(a), 2(a) and 2(b), each material layer is formed on the substrate 1001 and the active region is patterned in the same manner. The difference from the above embodiment is that in this embodiment, each of the first source/drain layer 1007 and the second source/drain layer 1011 include a material having etching selectivity relative to the material of the channel layer 1009. For example, the first source/drain layer 1007 and the second source/drain layer 1011 may include Si, while the channel layer 1009 may include SiGe, but the present disclosure is not limited thereto.

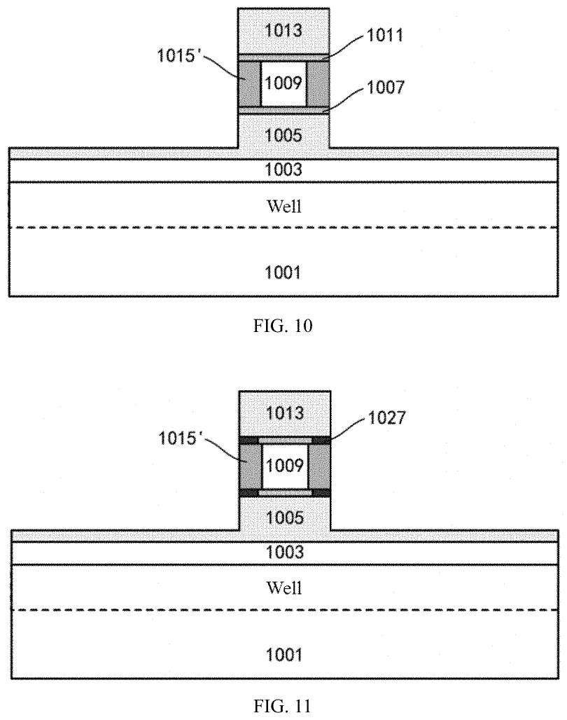

Similarly, the channel layer 1009 may be relatively recessed by selective etching. Here, due to etching selectivity, the first source/drain layer 1007 and the second source/drain layer 1011 may be substantially unaffected, as shown in FIG. 9. A sacrificial gate 1015′ may be formed according to the process described above in combination with FIG. 4, as shown in FIG. 10. Here, the sacrificial gate 1015′ surrounds the periphery of the channel layer 1009 and is located between the first source/drain layer 1007 and the second source/drain layer 1011.

In order to further reduce the overlap between the subsequently formed gate stack and the source/drain (reduce the parasitic capacitance) and improve an insulation reliability between the gate and the source/drain, as shown in FIG. 11, end portions of the first source/drain layer 1007 and end portions of the second source/drain layer 1011 may be relatively recessed by selective etching, and the resulting space may be filled with a dielectric material 1027. The dielectric material 1027 is between the sacrificial gate 1015′ (which will be replaced by the gate stack later) and the conductive layers 1005 and 1013, and surrounds the source/drain layers 1007 and 1011. Here, the end portion of the first source/drain layer 1007 and the end portion of the second source/drain layer 1011 may still protrude outward relative to the peripheral sidewall of the channel layer 1009 after being relatively recessed.

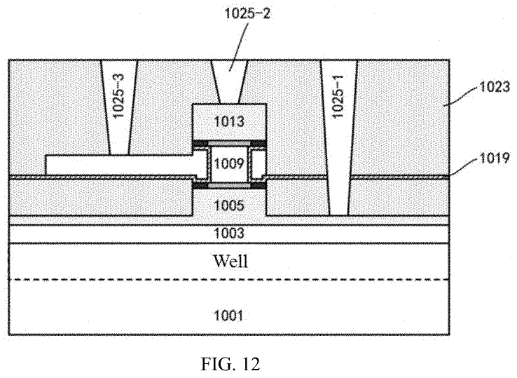

Next, as described above with reference to FIGS. 5 to 8(c), the gate replacement process may be performed to form the gate stack. As shown in FIG. 12, the dielectric material 1027 is inserted between the formed gate stack and the conductive layers 1005 and 1013, which helps to reduce the capacitance and improve the insulation reliability.

Other aspects of this embodiment may be the same as those in the above embodiment.

The semiconductor device according to an embodiment of the present disclosure may be applied to various electronic devices. For example, it is possible to form an integrated circuit (IC) by integrating a plurality of semiconductor devices and other devices (for example, a transistor in another form), thereby constructing an electronic device. Therefore, the present disclosure also provides an electronic device including the above-mentioned semiconductor device. The electronic device may also include components such as a display screen matched with an integrated circuit and a wireless transceiver matched with an integrated circuit. Such electronic device includes, for example, a smart phone, a computer, a tablet (PC), a wearable device, a mobile power supply, etc.

According to an embodiment of the present disclosure, a manufacturing method of a system on chip (SoC) is also provided. The method may include the above-mentioned method of manufacturing the semiconductor device. Specifically, a variety of devices may be integrated on the chip, at least some of which are manufactured according to the method of the present disclosure.

In the above description, the technical details such as patterning and etching of each layer are not described in detail. However, those skilled in the art should understand that various technical means may be configured to form layers, areas, etc. of desired shapes. In addition, in order to form the same structure, those skilled in the art may also design a method that is not completely the same as the method described above. In addition, although the respective embodiments are described above separately, this does not mean that the measures in the respective embodiments cannot be advantageously used in combination.

The embodiments of the present disclosure have been described above. However, these examples are for illustrative purposes only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should fall within the scope of the present disclosure.

1. A semiconductor device, comprising:
a substrate;
a first metallic layer, a channel layer and a second metallic layer which are sequentially disposed on the substrate: and
a gate stack formed around at least a part of a periphery of the channel layer,
wherein each of the first metallic layer, the second metallic layer, and the channel layer is of single crystal structure.

2. The semiconductor device according to claim 1, wherein:
at least a part of an interface between the first metallic layer and the channel layer is a coherent interface; and/or
at least a part of an interface between the second metallic layer and the channel layer is a coherent interface.

3. The semiconductor device according to claim 1, wherein:
an interface between the first metallic layer and the channel layer is a coherent interface; and/or
an interface between the second metallic layer and the channel layer is a coherent interface.

4. The semiconductor device according to claim 1, wherein:
a Schottky junction is formed between the first metallic layer and the channel layer; and
a Schottky junction is formed between the second metallic layer and the channel layer.

5. The semiconductor device according to claim 1, further comprising:
a first source/drain layer disposed between the first metallic layer and the channel layer; and
a second source/drain layer disposed between the second metallic layer and the channel layer,
wherein each of the first source/drain layer and the second source/drain layer is of single crystal structure.

6. The semiconductor device according, to claim 5, wherein:
at least a part of an interface between the first metallic layer and the first source/drain layer is a coherent interface; and/or
at least a part of an interface between the second metallic layer and the second source/drain layer is a coherent interface.

7. The semiconductor device according to claim 5, wherein:
an interface between the first metallic layer and the first source/drain layer is a coherent interface; and/or
an interface between the second metallic layer and the second source/drain layer is a coherent interface.

8. The semiconductor device according to claim 5, wherein:
an ohmic contact is formed between the first metallic layer and the first source/drain layer; and
an ohmic contact is formed between the second metallic layer and the second source/drain layer.

9. The semiconductor device according to claim 1, wherein a difference between a lattice constant of each of the first metallic layer and the second metallic layer and a lattice constant of the substrate is within a range of +/−2%.

10. The semiconductor device according to claim 1, wherein each of the first metallic layer and the second metallic layer comprises NiSi₂ or CoSi₂.

11. A semiconductor device, comprising:
a substrate;
a first conductive layer, a first source/drain layer, a channel layer, a second source/drain layer, and a second conductive layer which are sequentially disposed on the substrate; and
a gate stack formed around at least a part of a periphery of the channel layer,
wherein each of the first conductive layer, the second conductive layer, the first source/drain layer, the second source/drain layer, and the channel layer is of single crystal structure.

12. The semiconductor device according to claim 11, wherein a difference between a lattice constant of each of the first conductive layer and the second conductive layer and a lattice constant of the substrate is within a range of +/−2%.

13. The semiconductor device according to claim 11, wherein each of the first conductive layer and the second conductive layer comprises doped GaAs or doped GaAs:Si.

14. The semiconductor device according to claim 1, further comprising:
a leakage suppression layer disposed between the first metallic layer and the substrate or between the first conductive layer and the substrate.

15. The semiconductor device according to claim 14, wherein the substrate comprises a well region, and a pn junction is formed between the leakage suppression layer and the well region.

16. The semiconductor device according to claim 14, wherein the leakage suppression layer comprises an insulating layer of single crystal structure.

17. The semiconductor device according to claim 16, wherein a difference between a lattice constant of the insulating layer and a lattice constant of the substrate is within a range of +/−2%.

18. The semiconductor device according to claim 16, wherein the insulating layer comprises SrTiO₃, (LaY)₂O₃, LaAlO₃, or LaLuO₃.

19. The semiconductor device according to claim 5, further comprising:
dielectric layers which are respectively disposed between the gate stack and one of the first metallic layer and the first conductive layer, and between the gate stack and one of the second metallic layer and the second conductive layer, and are respectively surrounding the first source/drain layer and the second source/drain layer.

20. The semiconductor device according to claim 1, wherein an end portion of the gate stack close to the channel layer is self-aligned with the channel layer.

21. A method of manufacturing a semiconductor device, comprising:
sequentially forming a first metallic layer, a channel layer and a second metallic layer on a substrate;
patterning the first metallic layer, the channel layer and the second metallic layer into a predetermined shape; and
forming a gate stack around at least a part of a periphery of the channel layer.

22. The method according to claim 21, further comprising:
forming a first source/drain layer between the first metallic layer and the channel layer; and
forming a second source/drain layer between the second metallic layer and the channel layer.

23. The method according to claim 21, wherein each of the first metallic layer and the second metallic layer comprises NiSi₂ or CoSi₂.

24. A method of manufacturing a semiconductor device, comprising:
sequentially forming a first conductive layer, a first source/drain layer, a channel layer, a second source/drain layer, and a second conductive layer on a substrate;
patterning the first conductive layer, the first source/drain layer, the channel layer, the second source/drain layer, and the second conductive layer into a predetermined shape; and
forming a gate stack around at least a part of a periphery of the channel layer.

25. The method according to claim 24, wherein each of the first conductive layer and the second conductive layer comprises doped GaAs or doped GaAs:Si.

26. The method according to claim 21, further comprising:
forming a leakage suppression layer between the substrate and the first metallic layer or between the substrate and the first conductive layer.

27. The method according to claim 21, wherein forming each layer comprises epitaxial growing each layer of single crystal structure.

28. The method according to claim 26, further comprising:
forming a well region in the substrate,
wherein a pn junction is formed between the leakage suppression layer and the well region.

29. The method according to claim 26, wherein the leakage suppression layer comprises an insulating layer of single crystal structure.

30. The method according to claim 29, wherein the insulating layer comprises SrTiO₃, (LaY)₂O₃, LaAlO₃, or LaLuO₃.

31. An electronic device comprising an integrated circuit formed by the semiconductor device according to claim 1.

32. The electronic device according to claim 31, wherein the electronic device comprises a smart phone, a computer, a tablet, an artificial intelligence device, a wearable device, or a mobile power supply.
